(19) United States
(12) Patent Application Publication
(10) Pub. No.: US 2022/0416944 A1
(43) Pub. Date: Dec. 29, 2022

(54) METHOD OF PERFORMING A DISTRIBUTED TASK OVER A NETWORK

(71) Applicant: VICTORIA LINK LIMITED, Wellington (NZ)

(72) Inventors: Willem Bastiaan KLEIJN, Lower Hutt (NZ); Matthew Michael O'CONNOR, Karori (NZ)

(21) Appl. No.: 17/778,076

(22) PCT Filed: Nov. 20, 2020
(86) PCT No.: PCT/NZ2020/050155

§ 371 Date: May 19, 2022

(30) Foreign Application Priority Data
Nov. 20, 2019 (AU) 2019904365

(51) Int. Cl. H04L 1/00; H04L 67/10; H04L 45/48; H03M 13/19; H03M 13/00

(52) U.S. Cl. CPC H04L 1/0078; H04L 67/10; H04L 45/48; H03M 13/19; H03M 13/611

(57) ABSTRACT

An aspect of the invention provides a method of performing a distributed task over a network comprising a plurality of nodes. The method comprises: a plurality of network nodes observing (300) data; applying a first linear code function to the data observed by at least one network node of the plurality of network nodes to obtain (302) at least one function output; applying errors (304) to the at least one function output; a query node selected from the network nodes performing (308) a mixing procedure to aggregate node observations to obtain a first set of aggregated values until a stopping criteria (306) is satisfied; applying (312) a second linear code function to the set of aggregated values to obtain a second set of aggregated values returned to their observed domain; and the query node outputting (314) the second set of aggregated values.

### FIELD OF THE INVENTION

The invention relates to a method of performing a distributed task over a network. The invention is particularly suited to applications that require limits to be placed on the number of nodes within a network that contribute to the task.

### BACKGROUND TO THE INVENTION

With concepts such as the Internet of Things becoming more commonplace, greater emphasis must be placed on data privacy in large-scale public networks to make these secure without the threat of data theft.

Most current distributed processing techniques deal with improving the flexibility and convergence speed of algorithms for networks of finite size with no constraints on information sharing and no concept for expected levels of signal privacy.

Such techniques are not suited to maintaining data privacy in an unbounded public network, for example an unbounded public wireless sensor network (WSN).

In a distributed processing application within a WSN it is desirable to place limits on the number of nodes contributing to a distributed task. Global network consensus or routed summation are standard approaches for use with distributed tasks. There is a potential with such techniques for distant nodes to arrive at the same estimate as those near a query node. Furthermore, these techniques typically have no defence against unwanted nodes joining a task.

Such techniques have the potential to suffer from a lack of privacy, namely the ability for a subnet to determine its consensus or summation estimate without outside nodes learning of this estimate, or without the possibility of outside nodes forcefully joining this task.

Various approaches attempt to retain the privacy of individual node messages. However, the ability for aggregation tasks to spread through a network unchecked has not yet been addressed.

It is an object of at least preferred embodiments of the present invention to address at least some of the aforementioned disadvantages. An additional or alternative object is to at least provide the public with a useful choice.

### SUMMARY OF THE INVENTION

In accordance with an aspect of the invention, a method of performing a distributed task over a network comprising a plurality of nodes comprises: a plurality of network nodes observing data; applying a first linear code function to the data observed by at least one network node of the plurality of network nodes to obtain at least one function output; applying errors to the at least one function output; a query node selected from the network nodes performing a mixing procedure to aggregate node observations to obtain a first set of aggregated values until a stopping criteria is satisfied; applying a second linear code function to the set of aggregated values to obtain a second set of aggregated values returned to their observed domain; and the query node outputting the second set of aggregated values.

The term ‘comprising’ as used in this specification means ‘consisting at least in part of’. When interpreting each statement in this specification that includes the term ‘comprising’, features other than that or those prefaced by the term may also be present. Related terms such as ‘comprise’ and ‘comprises’ are to be interpreted in the same manner.

In an embodiment, the stopping criteria is satisfied when the query node has aggregated node observations from a maximum number of nodes.

In an embodiment, the method further comprises determining the maximum number of nodes at least partly from a Hamming distance.

In an embodiment, the method further comprises determining the maximum number of nodes at least partly by detecting a threshold number of symbol errors in the aggregated node observations.

In an embodiment, the method further comprises performing a routing procedure to ensure that the aggregated node observations do not include multiple observations from a single node.

In an embodiment, the routing procedure includes a tree protocol.

The invention in one aspect comprises several steps. The relation of one or more of such steps with respect to each of the others, the apparatus embodying features of construction, and combinations of elements and arrangement of parts that are adapted to affect such steps, are all exemplified in the following detailed disclosure.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting. Where specific integers are mentioned herein which have known equivalents in the art to which this invention relates, such known equivalents are deemed to be incorporated herein as if individually set forth.

In addition, where features or aspects of the invention are described in terms of Markush groups, those persons skilled in the art will appreciate that the invention is also thereby described in terms of any individual member or subgroup of members of the Markush group.

As used herein, ‘(s)’ following a noun means the plural and/or singular forms of the noun.

As used herein, the term ‘and/or’ means ‘and’ or ‘or’ or both.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9, and 10) and also any range of rational numbers within that range (for example, 2 to 8, 1.5 to 5.5, and 3.1 to 4.7) and, therefore, all sub-ranges of all ranges expressly disclosed herein are hereby expressly disclosed. These are only examples of what is specifically intended and all possible combinations of numerical values between the lowest value and the highest value enumerated are to be considered to be expressly stated in this application in a similar manner.

In this specification where reference has been made to patent specifications, other external documents, or other sources of information, this is generally for the purpose of providing a context for discussing the features of the invention. Unless specifically stated otherwise, reference to such external documents or such sources of information is not to be construed as an admission that such documents or such sources of information, in any jurisdiction, are prior art or form part of the common general knowledge in the art.

In the description in this specification reference may be made to subject matter which is not within the scope of the appended claims. That subject matter should be readily identifiable by a person skilled in the art and may assist in putting into practice the invention as defined in the presently appended claims.

Although the present invention is broadly as defined above, those persons skilled in the art will appreciate that the invention is not limited thereto and that the invention also includes embodiments of which the following description gives examples.

### BRIEF DESCRIPTION OF THE DRAWINGS

Preferred forms of the method of performing a distributed task will now be described by way of example only with reference to the accompanying figures in which:

FIG. 1 shows an example of an unbounded public wireless sensor network (WSN) in which the invention is configured to operate;

FIG. 2 shows an example of a node from FIG. 1;

FIG. 3 shows an example of a general processing task performed by a node;

FIG. 4 shows an example of a specific processing task performed by a node;

FIG. 5 shows an example of a method for performing a step of the processing task of FIG. 4; and

FIG. 6 shows an example of a specific processing task performed by a node.

### DETAILED DESCRIPTION

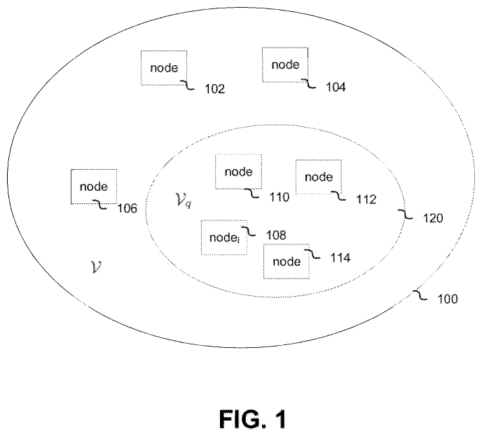

FIG. 1 shows an example of an unbounded public wireless sensor network (WSN) 100. The network 100 includes a plurality of nodes. Examples of nodes are shown at 102, 104, 106, 108, 110, 112 and 114. A plurality of the nodes is each equipped with an on-board processor, a two-way communication system, and a sensor for a specific signal processing task. Examples of node configurations are further described below.

Nodes within the network 100, or WSN, are configured to communicate with each other using their respective two-way communication systems.

Those nodes that are equipped with a sensor each hold observation data. When a user wishes to initiate a distributed task, the user selects a node that will henceforth be considered a query node for the distributed task. For both practical and privacy reasons, the query node spreads the task to a subset of nearby nodes.

In an embodiment a distributed task includes query node 108. The query node 108, shown in FIG. 1 as nodeᵢ, spreads or allocates the distributed task to nearby nodes for example node 110, node 112 and node 114. Nodes 108, 110, 112 and 114 collectively form a connected subnetwork 120.

In notations below the set of nodes forming the WSN 100 is referred to as [symbol] , and the set of nodes forming the subnetwork 120 is referred to as [symbol] _{q}, where [symbol] _{q}⊂ [symbol] .

As will be further described below, the subnetwork 120 collaboratively solves a distributed task while also limiting the ability of nodes to join the distributed task that are not within the subnetwork 120. Examples of nodes outside the subnetwork 120 include nodes 102, 104 and 106.

Practically, task subnet 120 that is smaller than network 100, allows for more efficient computations to be performed since information is not required to propagate through the entire public network 100. For privacy purposes this reduced information travel distance means that expected levels of privacy are more easily retained by excluding nodes that are very distant from a query node.

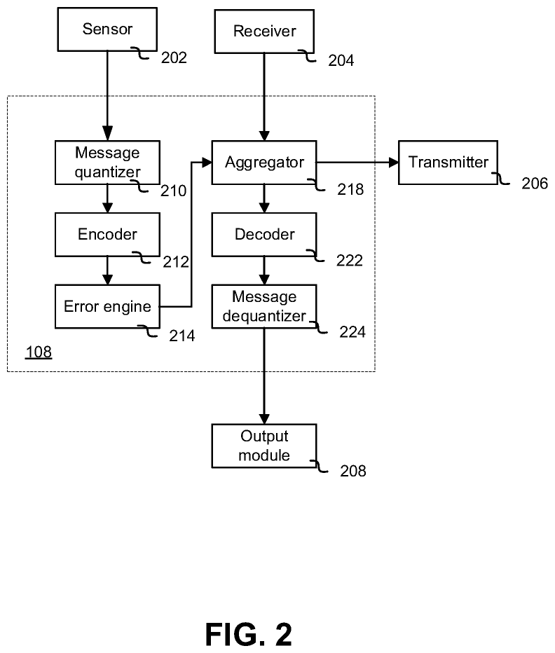

FIG. 2 shows an example of a node from FIG. 1, for example query node 108. In an embodiment the node 108 includes, or is connected to, a sensor 202, receiver 204, transmitter 206 and output module 208.

In an embodiment the sensor 202 is configured to perform a specific signal processing task. One example of a task performed by the sensor 202 is to monitor an acoustic signal.

It will be appreciated that the sensor 202 is one example of a device configured for data acquisition. In other embodiments, data is computed by data centre(s) and/or computer(s) in locations remote from the query node 108. In such cases the network 100 processes the data obtained from the data centre(s) and/or computer(s) as an alternative to the sensor 202 obtaining the data.

The receiver 204 is configured to receive data from other nodes within the network 100. In an embodiment the receiver 204 is configured to receive data from other nodes within the network 100 that are physically close to node 108. In an embodiment the nodes physically close to node 108 are referred to as a neighbourhood of nodes in relation to node 108. In an embodiment the neighbourhood of nodes includes nodes selected from network 100 and/or subnetwork 120.

The transmitter 206 is configured to transmit data to other nodes within the network 100. The receiver 204 and transmitter 206 are shown as separate modules for clarity. It will be appreciated that receiver 204 and transmitter 206 could be provided as either separate modules or a single combined module.

In an embodiment the output module 208 is configured to display or otherwise output the result of a query assigned to query node 108.

The query node 108 includes message quantizer 210. In an embodiment the message quantizer 210 is configured to receive observed data from the sensor 202. The observed data is quantized to produce messages mᵢ∀i∈ [symbol] _{q}.

An encoder 212 receives the messages from the message quantizer 210. The encoder 212 encodes the messages using a linear code to produce codewords cᵢ∀i∈ [symbol] _{q}.

An error engine 214 receives the codewords from the encoder 212 and applies random symbol errors. For example, U(n, λ) is a λ-dimensional discrete error vector with, for each dimension, integers drawn from {0, . . . , n−1}.

An aggregator 218 receives codewords containing errors from the error engine 214.

Aggregator 218 also receives codewords from receiver 204 that is configured to receive data transmitted from other nodes in the network 100, for example node 110 and node 102 from FIG. 1. As disclosed above, in an embodiment receiver 204 receives data transmitted from other nodes with a neighbourhood of nodes local to node 108.

In an embodiment aggregator 218 is configured to perform a mixing procedure taking as input the codewords obtained from the observations of sensor 202 and codewords received from other nodes in network 100 by receiver 204.

Aggregator 218 tests for at least one stopping criteria. In an embodiment there is only feed-forward flow of data towards the query node 108. In such cases the at least one stopping criteria includes a determination that the query node has received a response to the distributed task, such as the completion of an aggregation of values over a tree of nodes with query node 108 at its root.

In an embodiment the at least one stopping criteria is based at leas number of errors detected in the codewords. While the number of errors remain below a threshold the codewords are passed to transmitter 206 for transmission to other nodes in network 100.

It will be appreciated that the number of errors detected by aggregator 218 increases as other nodes in network 100 introduce additional errors using their own error engines.

Query node 108 uses output module 208 to output an estimate from aggregator 218.

Decoder 222 receives codewords from aggregator 218. Decoder 222 decodes the codewords to produce messages.

Message dequantizer 224 receives the messages from decoder 222. Message dequantizer 224 dequantizes the messages to produce data. The data is received by the output module 208 and presented to a user as an output of a task or query.

In an embodiment the message dequantizer 224 and/or the output module 208 are present only in the query node 108. In an embodiment the message dequantizer 224 and/or the output module 208 are present in other nodes in the neighbourhood of nodes, but are configured to operate where the node they are associated to is a query node.

In an embodiment message dequantizer 224 and/or output module 208 are present in a special class of nodes. In an embodiment, the network comprises nodes where each node can function as a query node, but where message dequantizer 224 and output module 208 are active only in the query node. In an embodiment, only a subset of the nodes of network 100 can function as a query node.

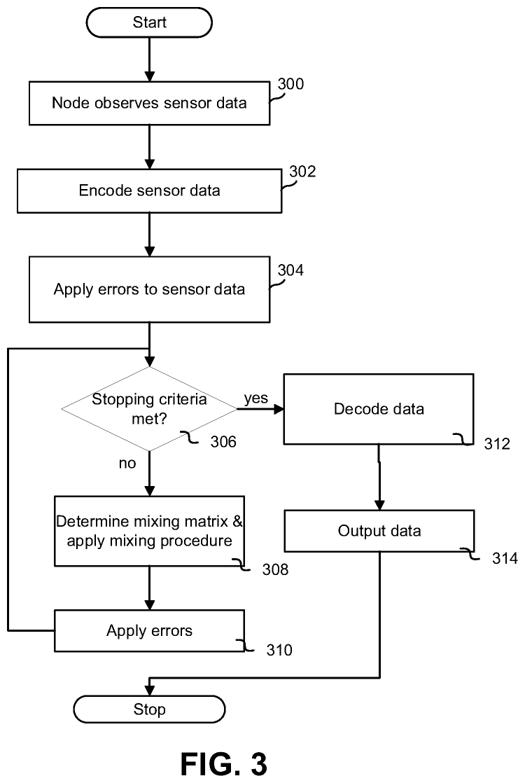

FIG. 3 shows an example of a processing task performed by at least some of the nodes of the network 100 and/or network 120 shown in FIG. 1. The method involves Distributed Private Aggregation (DPA).

In an embodiment, network 120 is defined for the processing task. Once network 120 is set up, the processing task is typically performed in a distributed manner without central co-ordination.

A formal notation for the method is set out below as:

```
Require: Task subnet [symbol] _{q}; message quantizer Q_{l,r}: message
  dequantizer R_{l,r}; linear encoder E_{l,n}^{r}; linear decoder D_{l,n}^{r};
  code length n; number of errors λ
  Symbol error index vectors eᵢ = a ~ U (n, λ) ∀i ∈ [symbol]
  Nodes observe uᵢ ∈ [symbol] ^{l} ∀i ∈ [symbol]
  Aggregation defined over task subnet ( [symbol] _{q}, [symbol] _{q}) ⊂ ( [symbol] , [symbol] )
  Encode cᵢ⁰ = E_{l,n}^{r} (Q_{l,r} (uᵢ)) ∈ [symbol] ᵣⁿ ∀i ∈ [symbol]
  Apply errors [cᵢ⁰]ₑ_{ᵢ} = b ~ U(r, λ) ∀i ∈ [symbol]
  k = 0
  while STOPPING CRITERIA == FALSE do
    Determine current mixing matrix P^{k+1} ∈ [symbol] ᵣ^{|} [symbol] _{q}^{| × |} [symbol] _{q}^{|}
    cᵢ^{k+1} ← [symbol]  [P^{k+1}]_{i,j}cⱼ^{k} ∀i ∈ [symbol] _{q}
    if ERRORS EACH ITERATION == TRUE then
      Apply errors [cᵢ^{k+1}]ₑ_{ᵢ} = b ~ U(r, λ) ∀i ∈ [symbol] _{q}
    end if
    k ← k + 1
  end while
  Decode uᵢ^{k} = R_{l,r} (D_{n,l}^{r}(cᵢ^{k}))∀i ∈ [symbol] _{q}
```

Query node 108 observes 300 data using sensor 202. Other nodes in network 100 and/or network 120 also observe data. Query node 108 and the other nodes in network 100 comprise a plurality of network nodes observing data.

In an embodiment the observed data at each node i is quantized to produce messages mᵢ∀i∈ [symbol] _{q}.

These messages are encoded 302 using a linear code to produce codewords cᵢ∀i∈ [symbol] _{q}. In an embodiment the linear code is defined in advance. For example, a first linear code function may be applied to the data observed by at least one network node of the plurality of network nodes to obtain at least one function output.

After encoding, errors are applied 304 to each node independently. In an embodiment these errors comprise random symbol errors. In an embodiment, U(n, λ) is a λ-dimensional discrete multivariate uniform distribution with integers drawn from {0, 1, . . . , n−1} independently for each dimension. In an embodiment the errors are applied to the at least one function output obtained by the first linear code function.

In an embodiment a general mixing procedure is performed by aggregator 218 (see FIG. 2) until a stopping criteria 306 is met. Mixing matrices P^{k+1} are determined 308 by a separate routine depending on the type of aggregation required. In an embodiment query node 108 (see FIG. 1) performs the mixing procedure to aggregate node observations to obtain a first set of aggregated values until a stopping criteria 306 is met.

In an example the method shown in FIG. 3 uses a prime field with r=p and has mixing matrices P^{k}∈ [symbol] ₚ^{n×n}. The update cᵢ^{k+1}← [symbol] [P^{k+1}]_{i,j}cⱼ^{k}∀i∈ [symbol] _{q} is performed using integer arithmetic modulo p, guaranteeing no overflow.

As more observations are included in the mixture, the number of symbol errors in the current aggregate instance increases. In an embodiment, additional errors are applied 310 at the same indices eᵢ if so desired.

In an embodiment, the maximum number of nodes that may join a task before erroneous decoding occurs is determined by the Hamming distance d of the linear code used and/or by the number of symbol errors introduced at each node.

In an embodiment the value of d and/or the number of symbol errors introduced at each node is/are predefined.

Once a stopping criteria is met, the codeword resulting from the mixing performed by the aggregator 218 is decoded 312. An example formal notation of the decoding process is uᵢ^{k}=R_{l,r}(D_{n,l}^{r}(cᵢ^{k})) ∀i∈ [symbol] _{q}.

In embodiment, decoding 312 includes applying a second linear code function to the set of aggregated values to obtain a second set of aggregated values returned to their observed domain. Query node 108 then outputs 314 an estimate of the private aggregation procedure. In an embodiment query node 108 outputs the second set of aggregated values.

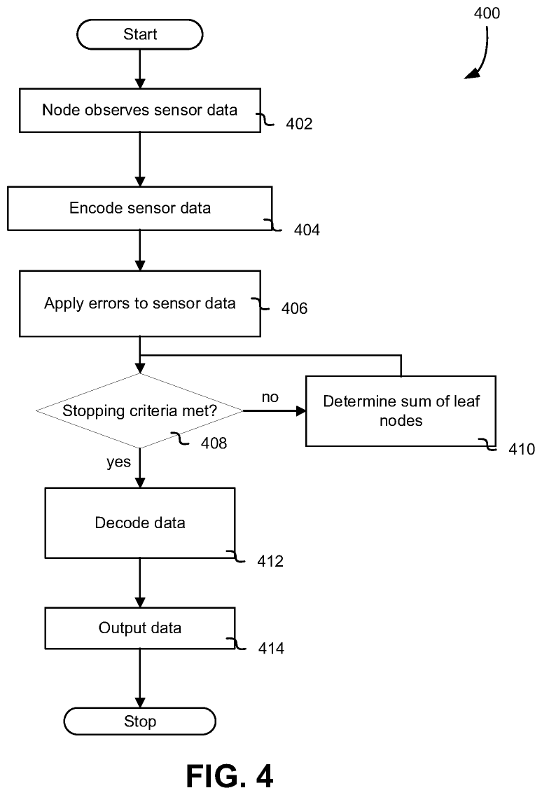

FIG. 4 provides a specialised example of the general method of FIG. 3. The method 400 shown in FIG. 4 shows an example of distributed private summation (DPS).

In many cases it may be desirable to perform a simple routed summation of node values over the query subnet [symbol] _{q} 120 (see FIG. 1). Given an appropriate routing procedure, a distributed routed summation has the potential to produce an output at the query node 108 significantly faster than repeatedly performing average consensus iterations across the entire network.

Some considerations come with performing a distributed summation. First, a routing procedure needs to be performed across the subnet so that messages are only included once in the summation as values are accumulated at the query node.

In an embodiment a tree protocol is used to remove certain subnet edges for this purpose, resulting in a tree graph rooted on the query node.

A formal notation for method 400 is set out below as:

```
Require: Task subnet [symbol] _{q}; prime field characteristic p; mes-
  sage quantizer Q_{l,p}; message dequantizer R_{l,p}; linear en-
  coder E_{l,n}^{p}; linear decoder D_{n,l}^{p}; code length n; number of
  errors λ
  Symbol error index vectors eᵢ = a ~ U (n, λ) ∀i ∈ [symbol]
  Nodes observe uᵢ ∈ [symbol] ^{l} ∀i ∈ [symbol] [symbol]
  Summation defined over task subnet ( [symbol] _{q}, [symbol] _{q}) ⊆ [symbol] , [symbol] )
  Construct tree edge set [symbol] _{q}⁰ ⊆ rooted at query node q
  mᵢ = Q_{l,p} (uᵢ), | [symbol] _{q}|max(||m₀||_{∞}, . . . , ||mₙ||_{∞}) ≤ p
  Encode cᵢ⁰ = E_{l,n}^{p}(mᵢ) ∈ [symbol] ₚⁿ ∀i ∈ [symbol] _{q}
  Apply errors [cᵢ⁰]ₑ_{ᵢ} = b ~ U(p, λ) ∈ [symbol] _{q}
  k = 0
  while [symbol] _{q}^{k} ≠ 0 do
    Define leaf nodes [symbol] _{q}^{k}, leaf parents [symbol] _{q}^{k}, and leaf edges [symbol]
_{q}^{k} = {(i, j) |j ∈ [symbol] ᵢ ∀i ∈ [symbol] _{q}^{k}} using [symbol] _{q}^{k}
    [P^{k+1}]_{i,j} = 1 for i == j,
    [P^{k+1}]_{i,j} = 1 for j ∈ [symbol] ᵢ ∩ [symbol] _{q}^{k} ∀i ∈ [symbol] _{q}^{k},
    [P^{k+1}]_{i,j} = 0 otherwise. [symbol]
_{q}^{k+1} ← [symbol] _{q}^{k}\ [symbol] _{q}^{k}
    cᵢ^{k+1} ← [symbol]  [P^{k+1}]_{i,j}c^{jk} ∀i ∈ [symbol] _{q}
    k ← k + 1
  end while
  u_{q}^{Sum} = R_{l,p}(D_{n,l}^{p}(c_{q}^{k}))
```

Method 400 describes a Distributed Private Summation (DPS) procedure for the specific case of prime fields r=p.

A query node 108 observes 402 data using sensor 202. Other nodes in the network 100 and/or network 120 also observe data. In an embodiment the observed data at each node i is quantized to map between [symbol] and [symbol] ₚ^{l}.

Sensor data is encoded 404 by linear encoder 212 (see FIG. 2) that maps between [symbol] ₚ^{l} and [symbol] ₚⁿ. A predefined code length n and a predefined number of symbol errors λ are also necessary.

Each node determines the number, λ, of codeword symbol indices that will be corrupted by error. These errors are applied 406 to the sensor data.

In an embodiment a summation procedure is performed by aggregator 218 until a stopping criteria 408 is met. In an embodiment, a stopping criteria is satisfied or met when the tree has been reduced to consist of the query node only.

Nodes continue to observe signals uᵢ ∀i∈ [symbol] . and receive data from other nodes. A summation task is defined over a task subnet [symbol] _{q}∈ [symbol] . In an embodiment the summation task includes determining 410 a sum of leaf nodes.

A set of edges [symbol] _{q}⁰ is determined that converts the general task graph into a tree graph rooted at the query node q. Initial codewords cᵢ⁰ are computed by first quantizing and then encoding node observations uᵢ. In an embodiment, aggregator 218 is configured to iteratively sum through the tree, from the leaf nodes to the root.

At each iteration k the tree edges [symbol] _{q}^{k} are used to define a leaf node set [symbol] _{q}^{k}, a set of direct leaf parent nodes [symbol] _{q}^{k}, and/or a set of all edges connected to leaf nodes denoted [symbol] _{q}^{k}.

Each leaf parent stores the sum of its previous codeword and the codewords of all its leaf neighbours (defined as the intersection of the leaf parent's neighbours and the current leaf nodes) as cᵢ^{k+1}.

The current tree edge set is then updated by removing the current leaf edge set [symbol] _{q}^{k} from the previous tree edge set.

Once the stopping criteria is met, the final output at the query node is the decoded and dequantized codeword after summation termination. The codeword is decoded 412 and output 414.

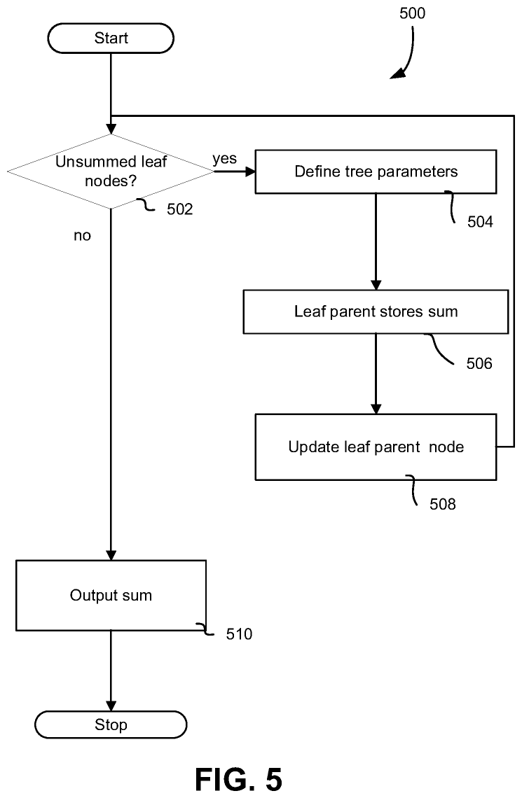

FIG. 5 shows one example of a method 500 for performing step 410 from FIG. 4 of determining a sum of leaf nodes. A set of edges [symbol] _{q}⁰ is determined that converts a general task graph into a tree graph rooted at the query node q. The method 500 iteratively sums through the tree until a stopping criteria 502 is met. One example of a stopping criteria is a determination that there are no unsummed leaf nodes remaining.

While the stopping criteria remains unmet, at each iteration k the tree edges. [symbol] _{q}^{k} are used to define 504 tree parameters including a leaf node set [symbol] _{q}^{k}, a set of direct leaf parent nodes [symbol] _{q}^{k}, and a set of all edges connected to leaf nodes denoted [symbol] _{q}^{k}.

Each leaf parent stores 506 the sum of its coded observed data and the codewords of all its leaf neighbours as cᵢ^{k+1}. This sum is defined as the sum of the codewords of the intersection residing in the leaf parent's neighbours and the current leaf nodes as well as the coded observation of the leaf parent.

The current tree edge set is then updated 508 by removing the current leaf edge set [symbol] _{q}^{k} from the previous tree edge set. The sums now present in each of the newly defined leaves, which are in the form of a codeword, are the result of method 500 for subsequent processing by method 400 from FIG. 4. Method 500 outputs 510 the codeword.

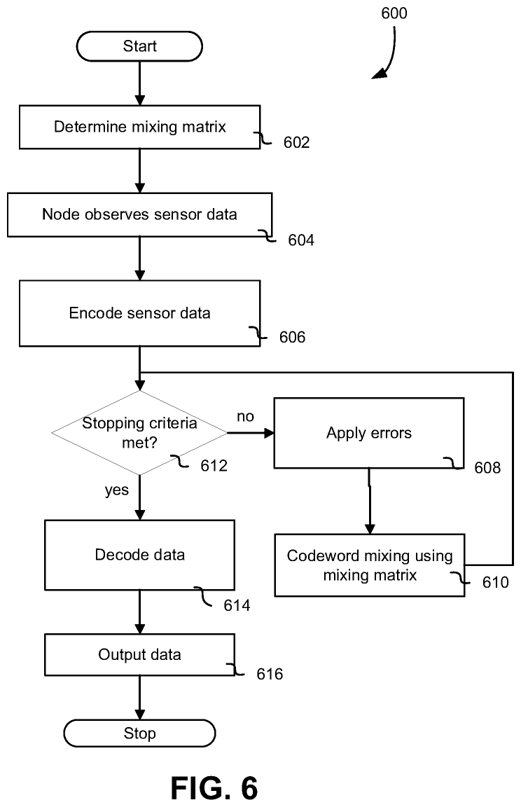

FIG. 6 shows an example of a processing task performed by at least some of the nodes of the network 100 and/or network 120 shown in FIG. 1. The method involves Distributed Private Consensus (DPC). This procedure allows distributed consensus to be performed in such a way that information travel distance through the network is limited.

A formal notation for the method is set out below as:

Require: Task subnet [symbol] _{q}; prime field characteristic p satisfy-
ing (7); message quantizer Q_{l,p}; message dequantizer R_{l,p};
linear encoder E_{l,n}^{p}; linear decoder D_{n,l}^{p}; code length n;
number of errors λ
Symbol error index vectors eᵢ = a ~ U(n, λ) ∀i ∈ [symbol]
Nodes observe uᵢ ∈ [symbol] ^{l} ∀i ∈ [symbol]
Consensus defined overtask subnet ( [symbol] _{q}, [symbol] _{q}) ⊆ ( [symbol] , [symbol] )
Determine consensus matrix P ∈ [symbol] ₚ^{|} [symbol] ^{_{q}}^{|×|} [symbol] ^{_{q}}^{|} from (8)-(l 1)
mᵢ = Q_{l,p} (uᵢ), | [symbol] _{q}|max(||m₀||_{∞}, . . . , ||mₙ||_{∞}) ≤ p
Encode cᵢ⁰ = E_{l,n}^{p}(mᵢ) ∈ [symbol] ₚⁿ ∀i ∈ [symbol] _{q}
[cᵢ⁰]ₑ_{ᵢ} ← b ~ U(p, λ) ∀i ∈ [symbol] _{q}
k = 0
while STOPPING CRITERIA == FALSE do
cᵢ^{k+1} ← Σ_{j∈N}_{ᵢ}[P]_{i,j}cⱼ^{k} ∀i ∈ [symbol] _{q}
k ← k + 1
end while
mᵢ^{Avg} = D_{n,l}^{p}(cᵢ^{k})∀i ∈ [symbol] _{q}
uᵢ^{Avg} = mod(| [symbol] |R_{l,p}(mᵢ^{Avg}),p)/| [symbol] _{q}| ∀i ∈ [symbol] _{q}.

The method 600 has the potential to allow distributed consensus to be performed in such a way that information travel through the network is limited.

A static mixing matrix P is determined 602. In an embodiment method 600 requires a predefined code length n and a predefined number of symbol errors λ. Since consensus is being performed over the finite field [symbol] ₚ particular care must be taken.

For example, the task subnetwork cardinality may not be an integer multiple of the field characteristic, le:

| [symbol] _{q}|≠αp,α [symbol] .

In practice, the above equation can be guaranteed by making the field size larger than the expected maximum task subnet cardinality, which may often be the case. Next, when determining 602 the mixing matrix P the entries of P may be determined by simultaneously satisfying the following equations:

P∈ [symbol] ₚ^{|ν}^{_{q}}^{|×|ν}^{_{q}}^{|}|{i,j}∉ [symbol] _{q}⇒[P]_{i,j}=0,

[symbol]

=P [symbol] ,

[symbol]

^{T}= [symbol] ^{T}P,

C_{P}(s)=sⁿ⁻¹(s−1),

where C_{P}(s) is the characteristic polynomial of matrix P, with indeterminates given by powers of s. The first 3 of the above equations are easy to satisfy, simply requiring P to share the sparsity pattern of the underlying physical network and be doubly stochastic. The requirement on the characteristic polynomial given by the 4^{th} equation is less straightforward, and requires distributed computation of the determinant of P.

Given that the above equations are satisfied, each node determines λ codeword symbol indices that will be corrupted by error for the consensus duration.

A query node 108 (see FIG. 1) observes 604 data using sensor 202 (see FIG. 2). Other nodes in the network 100 and/or network 120 also observe data. In an embodiment the observed data at each node i is quantized to map between [symbol] ^{l} and [symbol] ₚ^{l} to produce messages.

These messages are encoded 606 to map between [symbol] ₚ^{l} and [symbol] ₚⁿ.

Given these requirements, each node applies 608 errors by determining A codeword symbol indices that will be corrupted by error for the consensus duration.

Nodes continue to observe signals uᵢ ∀i∈ [symbol] , and a consensus task is defined over a task subnet [symbol] _{q}⊂ [symbol] . Initial codewords cᵢ⁰ are computed by first quantizing and then encoding node observations uᵢ.

At each stage of iterative consensus, each node i∈ [symbol] _{q} applies 608 errors to its predetermined symbol error indices by sampling new symbol values from U(r, s). The notation [⋅]eᵢ is used to select the elements of vector (⋅) at the indices contained in the vector eᵢ.

Each node shares its corrupted codewords with the local neighbourhood Nᵢ, and then takes a weighted average. In an embodiment, determining the weighted average includes performing 610 a mixing step. The mixing step 610 involves codeword mixing using the static mixing matrix P.

The dequantized local weighted averages are then quantized to give new codewords cᵢ^{k+1}∀i∈ [symbol] _{q}.

When the iterative consensus terminates 612 at the stopping criterion, such as after a number of iterations or when local update changes fall below some value, a codeword cᵢ^{k} may be decoded 614 and then dequantized to give an estimate uᵢ^{k} of the subnet average. In an embodiment, all nodes in the task subnet arrive at the mixed subnet value. The result is then output 616.

The foregoing description of the invention includes preferred forms thereof. Modifications may be made thereto without departing from the scope of the invention, as defined by the accompanying claims.

1. A method of performing a distributed task over a network comprising a plurality of nodes, the method comprising:
a plurality of network nodes observing data;
applying a first linear code function to the data observed by at least one network node of the plurality of network nodes to obtain at least one function output;
applying errors to the at least one function output by the at least one network node of the plurality of network nodes to obtain encoded node observations with errors;
a query node selected from the network nodes performing a mixing procedure to aggregate encoded node observations with errors to obtain a first set of aggregated values until a stopping criteria is satisfied;
applying a second linear code function to the set of aggregated values to obtain a second set of aggregated values returned to their observed domain; and
the query node outputting the second set of aggregated values.

2. The method of claim 1 wherein the stopping criteria is satisfied when the query node has aggregated encoded node observations with errors from a maximum number of nodes.

3. The method of claim 2 further comprising determining the maximum number of nodes at least partly from a Hamming distance.

4. The method of claim 2 further comprising determining the maximum number of nodes at least partly by detecting a threshold number of symbol errors in the aggregated encoded node observations with errors.

5. The method of claim 1 further comprising performing a routing procedure to ensure that the aggregated encoded node observations do not include multiple observations with errors from a single node.

6. The method of claim 5 wherein the routing procedure includes a tree protocol.
